(19) United States
(12) Patent Application Publication
(10) Pub. No.: US 2010/0089438 A1
(43) Pub. Date: Apr. 15, 2010

(54) PHOTOVOLTAIC MODULE AND ENERGY OR LIGHT PRODUCTION MODULES

(75) Inventors: Jean-Pierre Reyal, Eragny (FR); Jerome Giusti, Grenoble (FR); Klaus Bamberg, Lyon (FR)

Correspondence Address: OBLON, SPIVAK, MCCLELLAND MAIER & NEUSTADT, L.L.P., 1940 DUKE STREET, ALEXANDRIA, VA, 22314, US

(73) Assignees: ARCELORMITTAL-STAINLESS & NICKEL ALLOYS, Saint-Denis (FR); APOLLON SOLAR S.A.S., LYON (FR)

(21) Appl. No.: 12/526,964

(22) PCT Filed: Feb. 14, 2008
(86) PCT No.: PCT/FR2008/000195

§ 371 Date: Nov. 16, 2009

(30) Foreign Application Priority Data
Feb. 14, 2007 (EP) 07290184.6

(51) Int. Cl. H01L 31/048

(52) U.S. Cl. 136/251

(57) ABSTRACT

The invention relates to a module (1) for generating light or energy, comprising at least one light or energy generator including at least one semiconductor cell (2), the area of which is greater than 0.01 m², said cell being placed in a sealed enclosure maintained at a pressure below atmospheric pressure, said enclosure having a glass front side (3), a metal or metal alloy rear side (4) optionally coated on one or other of its faces, a peripheral sealing gasket (5), and electrical connectors (6) that are not fastened to said cells (2) or to said front side (3) and rear side (4), said rear side (4) being electrically isolated from said generators, characterized in that said rear side (4) has a metal or metal alloy thickness of less than 1 mm.

The invention relates more particularly to photovoltaic modules and to LED or OLED illumination modules.

The present invention relates to a module for generating energy or light, more particularly intended for the manufacture of photovoltaic modules for the generation of electricity from solar radiation, without in any way being limited thereto.

Silicon photovoltaic modules generally consist of assemblies of single-crystal or polycrystalline silicon cells, which are generally connected in series or in parallel and then placed between a transparent front side and a to rear side, with various polymer and/or adhesive films composed therebetween.

In general, the transparent front side is made of glass, facing the sun, with the purpose of letting the solar radiation pass through it but also of protecting the cell from various impacts. The rear side may be made of various materials. Glass will be used when the module has to be transparent, but a stack of polymers will preferably be used when said module may be opaque, thereby protecting the cells from mechanical attack.

The cells are connected together by means of copper strips, said “front contact” cells being connected from the front side of one cell to the rear side of the adjacent cell, whereas “rear contact” cells are connected from the rear side of one cell to the rear side of the adjacent cell.

Two manufacturing technologies for these modules are known, namely hot encapsulation and cold sealing. Hot encapsulation consists in stacking the successive films of the module, namely at least a glass front side, a transparent polymer film, mutually connected cells, a composite sold under the name Tedlar®, and a rear side coated with a thermally activatable adhesive, and in hot-pressing them. Depending on the requirements, various glass-fiber-reinforced films and polymer films may be added before the pressing operation, making it possible in particular to absorb, for example, the infrared and ultraviolet radiation and to recover the radiation in the visible range.

This technology has certain drawbacks, since the various films of the stack have a tendency to move relative to one another during the pressing operation. In particular, the forces generated are sufficient to make the silicon cells and the copper contacts move relative to one another, resulting in poor electrical efficiency.

As regards cold sealing, this consists in stacking the constituent successive films of the module and then in placing a peripheral sealing gasket around the module so as to produce a sealed enclosure. This enclosure is then flushed with an inert gas, before a partial vacuum is created therein by suction, thereby sealing the module by compressing the peripheral gasket. The reader may refer in particular to patent application WO 2004/095586 for a detailed description of this manufacturing process.

The above document particularly recommends the use of a rigid rear side, which may be made of glass of large thickness, ranging from 2 to 4 mm, or by a surface-treated rigid metal sheet. However, the flatness heterogeneities of such sides necessarily result in a variation in the connector contact areas and contact forces in silicon cells. This curvature variation may sometimes even be as far as to cause the cells to rupture and in all cases is unfavorable to good electrical efficiency.

The aim of the present invention is therefore to remedy the drawbacks of the modules of the prior art by providing an energy or light generation module having a lastingly improved energy efficiency and a lifetime of at least 30 years. This means in particular maintaining the partial vacuum within the enclosure of the module protecting the cells from mechanical attack, improving the corrosion resistance, and maintaining water vapor impermeability over this same period.

For this purpose, a first subject of the present invention is a module for generating light or energy, comprising at least one light or energy generator including at least one semiconductor cell, the area of which is greater than 0.01 m², said cell being placed in a sealed enclosure maintained at a pressure below atmospheric pressure, said enclosure having a glass front side, a metal or metal alloy rear side optionally coated on one or other of its faces, a peripheral sealing gasket, and electrical connectors that are not fastened to said cells or to said front side and rear side, said rear side being electrically isolated from said generators, characterized in that said rear side has a metal or metal alloy thickness of less than 1 mm.

The module according to the invention may also include various features, taken by themselves or in combination, namely:
the module comprises at least one cell, the area of which is equal to or greater than 0.015 m²;
the rear side has a metal or metal alloy thickness of 0.3 mm or less and in that the rear side has an expansion coefficient α_{RS} between 0 and 100° C. such that the difference in absolute value between said coefficient and the expansion coefficient α_{SC} of the semiconductor between 0 and 100° C. is given by:

|α_{RS}−α_{SC}|≦15×10⁻⁶K⁻¹;
the rear side has an expansion coefficient α_{RS} between 0 and 100° C. such that the difference in absolute value between said coefficient and the expansion coefficient α_{SC} of said semiconductor between 0 and 100° C. is given by:

|α_{RS}−α_{SC}|>5×10⁻⁶K⁻¹,

the rear side having a metal or metal alloy thickness of 0.3 mm or less and being shaped in the zones located between the semiconductor cells, in such a way that it does not come into contact with the edges of these cells during operation of the module;
the rear side has a metal or metal alloy thickness of greater than 0.3 mm and in that the rear side has an expansion coefficient α_{RS} between 0 and 100° C. such that the difference in absolute value between said coefficient and the expansion coefficient α_{SC} of the semiconductor is given by:

|α_{RS}−α_{SC}|≦4.5×10⁻⁶K⁻¹;
the rear side is isolated from said cells by means of an insulating coating chosen from non-conducting polymers; and
the coating comprises electrically insulating but thermally conducting compounds capable of extracting heat from the module, such as aluminum nitride powders.

In a preferred embodiment, the module according to the invention is a photovoltaic module, which may more particularly preferably include any one of the following features, by themselves or in combination, namely:
the semiconductor is silicon and the rear side has a thickness of 0.3 mm or less and consists of an iron-nickel alloy containing 34 to 42% nickel, with or without a corrosion protection coating;
the semiconductor is silicon, and the rear side has a thickness of 0.3 mm or less, consists of F18MT stainless steel and is shaped in the zones between the semiconductor cells, in such a way that the rear side does not come into contact with the edges of these cells;
the rear side has a thickness greater than 0.3 mm, consists of an N485 iron-nickel alloy or F18MT stainless steel and is shaped in the zones between the semiconductor cells, in such a way that the rear side does not come into contact with the edges of these cells; and
the rear side has a thickness greater than 0.3 mm, consists of galvanized carbon steel and is shaped in the zones between the semiconductor cells, in such a way that the rear side does not come into contact with the edges of these cells.

In other preferred embodiments, the module according to the invention may take the form of a display screen or an LED or OLED illumination module.

The terms N485, F18MT, N426, N475, F17T and 316L refer to the standards that define the compositional ranges of the steels and alloys in question (NF EN 10088-2 in the case of stainless steels and ISO 6372 in the case of iron-nickel alloys).

The present inventors have found that when a metal or metal alloy rear side is used that has a thickness of less than 1 mm and preferably less than 0.6 mm, i.e. a non-rigid rear side, it is therefore possible to adapt the mechanical behavior of this rear side to that of the rest of the module and therefore to limit any degradation of the modules as a result of thermal cycling, but above all to permanently improve the energy efficiency of the generators.

In particular, it has been found that, below a thickness of 0.3 mm, it is particularly advantageous to adapt the expansion of the rear side to the expansion of the cells of the generators inserted into the modules. This is because it has been observed that, after creating the vacuum, the metal sheets with such thicknesses can follow the shape of these generators, and the main risk of deterioration then stems from the difference in expansion between these two elements as soon as the module starts to operate, when these cells have an area of greater than 0.01 m², corresponding in particular to generators measuring 100 mm by 100 mm.

When it is not possible or desirable to choose a material having an expansion coefficient matched to that of the generator cells, it is then possible to maintain the integrity of these cells by a shaping of the rear side, in the zones between the cells. This shaping operation is carried out in such a way that the rear side never comes into contact with the edges of the cells during is operation of the latter.

The present inventors have furthermore found that, for thicknesses between 0.3 mm and 1 mm, and preferably between 0.3 mm and 0.6 mm, it is also advantageous to match the expansion of the rear side to the expansion of the silicon. This is because, for these greater thicknesses, the metal sheet deforms less and conforms less closely to the generators, but the main risk of degradation comes from fatigue failure of the cells due to the cyclic stress that they are subjected to during operation of the module.

These thicknesses in question are those of the metal or metal alloy sheets, ignoring the possible coating thicknesses.

In preferred embodiments, the module according to the invention may consist of a photovoltaic module, such as a module based on silicon cells, or else a display screen of the OLED (organic light-emitting diode) or an LED (light-emitting diode) or OLED lighting module.

The following description refers to a photovoltaic module comprising silicon cells, but of course the invention is not limited thereto and rather it encompasses, especially, all photovoltaic modules, all display screens and all LED or OLED illumination modules.

As regards photovoltaic modules, it may thus be advantageous to use cells made of single-crystal or polycrystalline silicon, or made of gallium arsenide, or any other suitable semiconductor.

The features and advantages of the invention will become apparent on reading the following description, given solely by way of example and with reference to the appended drawings which show:

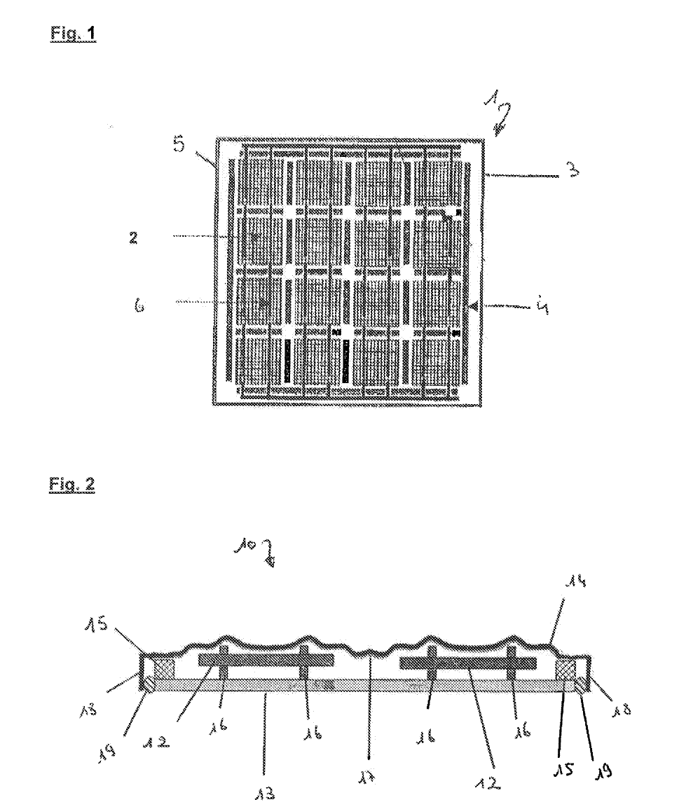

FIG. 1: a top view of a first photovoltaic module of sixteen silicon cells according to the invention;

FIG. 2: a sectional view of a second module having four cells according to the invention, which is provided with a thin rear side;

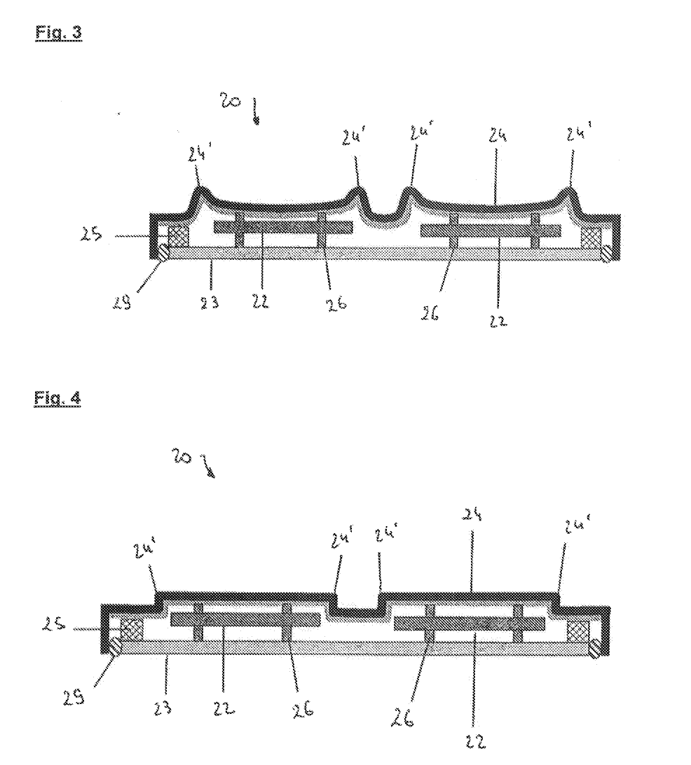

FIG. 3: a sectional view of a third module having four silicon cells according to the invention, with a shaped rear side, before said module is evacuated;

FIG. 4: a sectional view of the module of FIG. 3, after said module has been evacuated; and

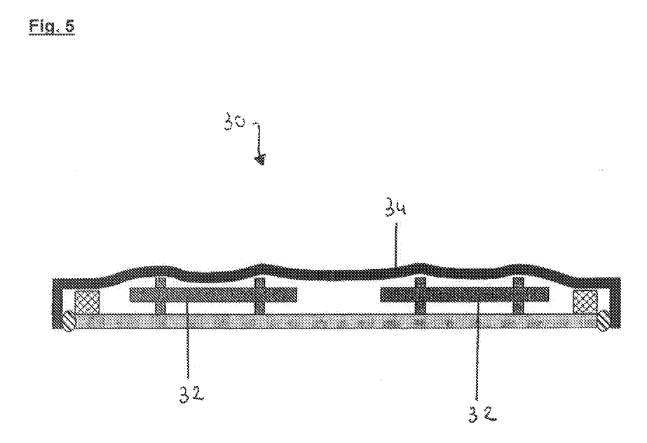

FIG. 5: FIG. 2: a sectional view of a fourth module having four cells according to the invention, which is provided with a thick rear side.

FIG. 1 shows schematically, in a top view, a front-contact photovoltaic module 1 made up of 16 semiconductor cells 2 of square shape, the total area of which is 0.0156 m². The cells 2 are arranged in a matrix fashion between a glass front side 3 and a metal rear side 4 according to the invention. A sealing gasket 5 made of a polyolefin, such as for example a poly-butylene is placed over the entire periphery of the module 1.

It is preferable to use a glass front side of high transmission, having good mechanical strength (solar-lime glass), the expansion coefficient of which, between 0 and 100° C. is close to 10×10⁻⁶ K⁻¹. The front side generally has a thickness of less than 6 mm, a typical value being 3 to 4 mm.

The cells 2 are connected together by contact with an array of copper connectors 6 which are in contact with the front side 3 and the rear side 4 of the module 1 without being fastened to them or to the cells 2.

During manufacture of the module, the sealed internal volume of the module is filled with argon. A partial vacuum is then formed by suction, so as to ensure contact pressure sufficient to provide electrical conduction without soldering the copper connection contacts 6 of the cells 2. These contacts 6 may slide over the glass front side 3, but do not slide against the rear side 4, which is too rough for this. It will therefore be understood that any movement of the rear side 4, by expansion due to heat for example, may damage the cells 2.

The modules according to the invention therefore have a sealed internal volume maintained at a pressure below atmospheric pressure, and preferably maintained at a pressure between 100 and 700 mbar and generally about 500 mbar.

Apart from a front side, a rear side and semiconductor cells, the modules according to the invention may include various films of material, in coating form or in independent film form, depending on the materials and on the required thicknesses.

Because of the requirements, reinforcing materials and materials for in particular absorbing infrared and ultraviolet radiation and for recovering radiation in the visible range, for example, may thus be added.

The metal sheets, which are not naturally resistant to oxidation, could be coated with a protective film on both their external faces.

Specifically, the metal parts of the photovoltaic modules must be resistant to atmospheric corrosion for 30 years in order to maintain the partial vacuum essential for the electrical contacts. In particular, they must be resistant to:
pitting corrosion;
stress corrosion; and
galvanic corrosion.

All types of coatings are conceivable, and in particular those used in the building industry, in the terrestrial and maritime transport industry, or those used on pipes, such as electrodeposition or PE-CVD (plasma-enhanced chemical vapor deposition) of nickel or other metals, hot-dip tinning, Zn electrodeposition, paint coating, cataphoretic protection, etc.

Moreover, the internal faces of the rear sides according to the invention must be electrically isolated from the generators of the modules. Any suitable insulating coating may be used for this purpose, such as a polymer coating, a thin oxide film or a thick film of insulator deposited by screen printing. The rear side may also be isolated, thanks to the adhesive optionally present for assembling the module.

In particular, it is preferred to use a coating that includes particles for continuously extracting heat from the module, such as for example aluminum nitride, in particular in powder form.

In one particular embodiment, the internal face of the rear side may be covered with a succession of coatings, the expansion coefficients of which between 0 and 100° C. will form a gradient so as to partly compensate for a difference in expansion between the rear side and the semiconductor cells. Such an arrangement may allow at most a 1×10⁻⁶ K⁻¹ matching.

In a first embodiment, it is preferred to use a module rear side having a thickness of 0.3 mm or less. As already indicated previously, the present inventors have found that, below a thickness of 0.3 mm, it is particularly advantageous to match the expansion of the rear side to the expansion of the generators inserted into the modules, as it is then observed that the metal sheets follow the shape of these generators.

Thus, in the case of a silicon photovoltaic module, a thin sheet having an expansion coefficient between −50° C. and +100° C. close to that of silicon (about 4×10⁻⁶ K⁻¹) makes it possible both to improve the electrical performance of the modules and to prevent the photovoltaic cells from cracking.

FIG. 2 shows schematically a module 10 having four silicon cells 12, with a 0.2 mm thick rear side 14 made of Invar®. The module 10 also has a soda-lime glass front side 13 and a poly-butylene peripheral gasket 15. The cells 12 are connected to copper connectors 16 which slide on the glass front side 13.

The rear side 14 is coated on its internal face with a film of adhesive 17. The rear side 14 closely conforms to the cells 12 and is folded over along its edges 18. To seal the module 10, a silicone gasket 19 is formed between the edges 18 and the front side 13.

The following improvements are in particular observed:
the foil closely conforms to the photovoltaic cells under the effect of the partial vacuum;
the pressure on the electrical contacts is high and uniformly distributed; and
the difference in expansion (between silicon and metal sheet) is too small to shear and crack the ends of the cells.

Since the expansion of silicon is generally between 2.5×10⁻⁶ K⁻¹ and 4.5×10⁻⁶ K⁻¹, it is preferable for the expansion difference between the thin rear side and the silicon photovoltaic cells not to exceed 5×10⁻⁶ K⁻¹. Consequently, the expansion of the thin rear sides for such a silicon cell must generally be between 0 and 9.5×10⁻⁶ K⁻¹.

### EXAMPLE 1

### Behavior of a Module with an Unshaped Rear Side

A series of photovoltaic modules having a glass front side and a thin metal rear side made of various materials was produced, the module being sealed by a peripheral organic gasket and by a silicone gasket. The modules produced had silicon cells the expansion coefficient between 0 and 100° C. of which being α_{SC}=4.5×10⁻⁶ K⁻¹.

The front sides were soda-lime glass plates 3 mm in thickness.

The rear sides were not shaped, and were therefore flat, before evacuation, with the exception of their edges, which were folded over as shown in FIG. 2.

The behavior of these modules was tested after the silicon photovoltaic cells had undergone a series of 200 cycles between −45° C. and +85° C.

The results of these tests are given in Table 1 below:

TABLE 1

| | | Thickness | Composition | α_{RS} | | State of |
|---|---|---|---|---|---|---|
| Test | Rear side | (mm) | (wt %) | (10⁻⁶ ° K⁻¹) | \|α_{RS} − α_{SC}\| | the Si cells |
| 1* | Invar ® | 0.1 | 36Ni—Fe | 1.1 | 3.4 | good |
| 2* | N42 | 0.1 | 42Ni—Fe | 3.8 | 0.7 | good |
| 3* | Oliver P ® | 0.1 | 29Ni—18Co—Fe | 6.2 | 1.7 | good |
| 4 | N485 | 0.15 | 48Ni—6Cr—Fe | 9.2 | 4.7 | good |
| 5 | 316L | 0.15 | 17.5Cr—12.5Ni—2.5Mo—Fe | 16 | 11.5 | cracks |
| | Stainless | | | | | |

*according to the invention.

The table shows the good behavior of the modules according to the invention, which alone provide a satisfactory state of the silicon cells.

### EXAMPLE 2

### Electrical Efficiency

Electrical tests were also carried out on a first module having six silicon cells with a 0.22 mm thick Invar® rear side. The metal rear side was flat before evacuation, with the exception of its edges, and did not have coatings modifying the expansion coefficient of the rear side.

Text 1—Damp Heat Test

These tests consisted in determining the variation in the form factor FF of the module over more than 3000 hours at a temperature of 85° C. and 85% relative humidity according to the IEC 61215 standard (damp heat test). The results are given in Table 2 below:

TABLE 2

| | Six glass-Invar ® cells |
|---|---|
| Hours | % FF |
| 0 | 77 |
| 500 | 76.8 |
| 1000 | 77 |
| 1500 | 77 |
| 2000 | 76 |
| 3000 | 77 |

This table shows that the use of an Invar® rear side greatly stabilizes the electrical efficiency of the module over the course of time.

Test 2—Thermal Cycling Test

Tests were then continued with a module having twelve silicon cells, with a 0.22 mm thick flat Invar® rear side.

The tests were aimed at determining the variation in the form factor FF of the module over the course of a succession of 200 thermal cycles of 6 hours between −40° C. and +85° C. according to the IEC 61215 standard (thermal cycling test).

The measured form factors of the module according to the invention showed a 0.3% variation in amplitude.

The form factor of the module according to the invention was shown to be much more stable over time than that of a module of the prior art.

In a second embodiment, it was preferred to use a rear side having an expansion coefficient between 0 and 100° C. that is far from that of the semiconductor by more than 5×10⁻⁶ K⁻¹ and having a thickness of 0.3 mm or less. To prevent the semiconductor cells breaking, the rear side was shaped, as shown in FIGS. 3 and 4.

Thus, FIG. 3 shows a module 20 before evacuation, comprising silicon cells 22, a glass front side 23, a metal rear side 24, a polybutylene peripheral gasket 25 and a silicone gasket 29. The cells 22 were connected together by copper ribbons 26. The rear side 24 had a series of shaped zones 24′, which surrounded the periphery of each cell 22, thus structuring the rear side 24. This structuring may also be seen in FIG. 1, which shows a module 1 having a shaped rear side 4, seen from above, having shaped zones referenced 4′ between the cells 2.

After the module 20 has been evacuated, it may be seen in FIG. 4 that the zones 24′ are positioned under the effect of the partial vacuum, taking the form of approximately square boxes surrounding each cell 22, at a certain distance therefrom.

This shaping operation may be carried out by any suitable technical means, such as for example by damping. The dimensions and the precise location of the zones 4′, 24′ depend on the partial vacuum within the module 1, 20, but also on the expansion coefficient between 0 and 100° C. of the rear side and of the front side, on the thicknesses of the front and rear sides, on the mechanical properties of the front and rear sides (yield strength) and on the size of the semiconductor cells. The dimensions and the location of the zones 4′, 24′ may be easily determined by a person skilled in the art case by case, in particular by means of standard software for simulating the behavior of materials. In all cases, they are calculated so as to avoid any contact between the rear side and the ends of the cells during operation of the module, in particular during the thermal cycles to which the module will be subjected.

In a third embodiment, it is preferred to use a module rear side made from a sheet having a thickness greater than 0.3 mm.

As may be seen schematically in the module 30 shown in FIG. 5, the rear side 34 again deforms, but no longer conforms closely to the silicon cells 32. However, this rear side 34 has a rough rear face owing to the presence of a film of adhesive (not shown). During operation of the module 30, the cells 32 will therefore be in contact with the rear side 34. It is therefore recommended to choose for this rear side a material having an expansion coefficient between 0 and 100° C. close to that of the semiconductor so as to prevent fatigue failure of the cells.

Since expansion of silicon is generally between 2.5×10⁻⁶ K⁻¹ and 4.5×10⁻⁶ K⁻¹, it is preferable for the difference in expansion between the thin rear side and the silicon photovoltaic cells not to exceed 4.5×10⁻⁶ K⁻¹. Consequently, the expansion of the thin rear sides for such a silicon cell must be between 0 and 9×10⁻⁶ K⁻¹.

### EXAMPLE 3

### Behavior of the Module

A series of photovoltaic modules having a 3 mm thick soda-lime glass front side and a metal rear side made of various materials was produced, the module being sealed by a peripheral organic gasket and by a silicone gasket. The modules produced had silicon cells having an expansion coefficient of about 4.5×10⁻⁶ K⁻¹. The rear sides were flat before evacuation, with the exception of their edges, and did not include coatings modifying the expansion coefficient of the rear side.

The behavior of these modules was tested after the silicon photovoltaic cells had undergone a series of 500 cycles of 6 hours between −45° C. and +85° C.

The results of these tests are given in Table 4 below:

TABLE 4

| | | Thickness | Composition | α_{RS} | | State of |
|---|---|---|---|---|---|---|
| Test | Rear side | (mm) | (wt %) | (10⁻⁶ ° K⁻¹) | \|α_{RS} − α_{SC}\| | the Si cells |
| 1* | N426 | 0.4 | 42Ni—6Cr—Fe | 6.9 | 2.4 | good |
| 2* | Titanium | 0.4 | Ti | 8.6 | 4.1 | good |
| 3* | N475 | 0.4 | 47Ni—7Cr—Fe | 8.7 | 4.2 | good |
| 4 | F17T | 0.4 | 17Cr—0.4Ti—Fe | 10.2 | 5.7 | cracks |
| 5 | F18MT | 0.4 | 18Cr—2.1Mo—0.3Ti—Fe | 11.2 | 6.7 | cracks |
| 6 | 316L | 0.4 | 17.5Cr—12.5Ni—2.5Mo—Fe | 16 | 11.5 | cracks |
| | Stainless | | | | | |
| 7 | Aluminum | 0.4 | Al > 90% | 23 | 18.5 | cracks |

*according to the invention.

This table shows that only the modules having a suitably chosen expansion coefficient relative to the semiconductor exhibit satisfactory fatigue behavior.

For the modules having rear sides with too high an expansion coefficient, it is necessary to structure these rear sides, as described in detail in the case of the rear sides with a thickness of less than 0.3 mm.

The modules according to the invention, whether their rear sides are structured or not, all provide good mechanical protection of the rear of the semiconductor cells and excellent water vapor impermeability.

1. A module for generating light or energy, comprising at least one light or energy generator comprising at least one semiconductor cell, the area of which is greater than 0.01 m², said cell being placed in a sealed enclosure maintained at a pressure below atmospheric pressure, said enclosure having a glass front side, a metal or metal alloy rear side optionally coated on one or other of its faces, a peripheral sealing gasket, and electrical connectors that are not fastened to said cells or to said front side and rear side, said rear side being electrically isolated from said generators, wherein said rear side has a metal or metal alloy thickness of less than 1 mm.

2. The module according to claim 1, wherein said rear side has a metal or metal alloy thickness of 0.3 mm or less and an expansion coefficient a RS between 0 and 100° C. wherein the difference in absolute value between said coefficient and the expansion coefficient α_{SC} of said semiconductor between 0 and 100° C. is given by:

|α_{RS}−α_{SC}|≦15×10⁻⁶K⁻¹.

3. The module according to claim 1, wherein said rear side has an expansion coefficient α_{RS} between 0 and 100° C. wherein the difference in absolute value between said coefficient and the expansion coefficient α_{SC} of said semiconductor between 0 and 100° C. is given by:

|α_{RS}−α_{SC}|>5×10⁻⁶K⁻¹,
said rear side having a metal or metal alloy thickness of 0.3 mm or less and being shaped in the zones located between said semiconductor cells, wherein said rear side does not come into contact with the edges of said semiconductor cells during operation of the module.

4. The module according to claim 1, wherein said rear side has a metal or metal alloy thickness of greater than 0.3 mm and an expansion coefficient α_{RS} between 0 and 100° C. such that the difference in absolute value between said coefficient and the expansion coefficient α_{SC} of the semiconductor is given by:

|α_{RS}−α_{SC}|≦4.5×10⁻⁶K⁻¹.

5. The module according to claim 1, wherein said rear side is isolated from said cells by an insulating coating of a non-conducting polymer.

6. The module according to claim 5, wherein said coating comprises electrically insulating but thermally conducting compounds capable of extracting heat from said module.

7. The module according to claim 1, wherein the module is a photovoltaic module.

8. The photovoltaic module according to claim 7, wherein said semiconductor is silicon and said rear side has a thickness of 0.3 mm or less and is an iron-nickel alloy comprising 34 to 42% nickel, with or without a corrosion protection coating.

9. The photovoltaic module according to claim 7, wherein said semiconductor is silicon, and said rear side has a thickness of 0.3 mm or less, is F18MT stainless steel and is shaped in the zones between the semiconductor cells, wherein the rear side does not come into contact with the edges of these cells.

10. The photovoltaic module in according to claim 7, wherein said rear side has a thickness greater than 0.3 mm, is an N485 iron-nickel alloy or F18MT stainless steel and is shaped in the zones between the semiconductor cells, wherein the rear side does not come into contact with the edges of these cells.

11. The photovoltaic module according to claim 7, wherein said rear side has a thickness greater than 0.3 mm, is galvanized carbon steel and is shaped in the zones between the semiconductor cells, wherein the rear side does not come into contact with the edges of these cells.

12. The module according to claim 1, wherein the module is a display screen.

13. The module according to claim 1, wherein the module is an LED or OLED illumination module.
